(19) United States
(12) Patent Application Publication
(10) Pub. No.: US 2026/0343079 A1
(43) Pub. Date: Oct. 29, 2026

(54) CASTELLATED IMAGE SENSOR MODULE ARCHITECTURE

(71) Applicant: Datalogic IP Tech S.R.L., Lippo Di Calderara Di Reno (BO)

(72) Inventors: Simone STEFANINI, Bologna (IT); Stefano BONESI, Vigarano Mainarda (IT); Michele SUMAN, Ponte San Nicolò (IT); Mattia FABBRI, Gatteo (IT)

(21) Appl. No.: 19/187,621

(22) Filed: Apr. 23, 2025

(51) Int. Cl. H04N 23/54; H04N 23/55; H05K 1/11; H05K 1/14; H05K 1/181; H05K 3/341; H05K 3/36

(52) U.S. Cl. CPC H04N 23/54; H04N 23/55; H05K 1/111; H05K 1/141; H05K 1/181; H05K 3/341; H05K 3/36; H05K 2201/032; H05K 2201/09372; H05K 2201/10121

(57) ABSTRACT

The technology disclosed herein relates to methods, devices, components, and techniques associated with a particular castellated camera module (e.g., having castellated pads along one or more edges of the printed circuit board). The castellated camera module, for example, may include an image sensor soldered on a circuit board (e.g., the printed circuit board having the castellated pads), a housing (for a lens barrel) above the image sensor, the lens barrel being affixed (e.g., glued) to the housing. The castellated camera module may be affixed to a primary circuit board by an adhesive (e.g., a low temperature curing thermally conductive adhesive) so that the castellated image sensor module is electrically and mechanically connected to the primary circuit board.

### BACKGROUND

Generally, scanners, such as barcode scanners, have printed circuit boards (PCBs), optics, electronic components, and other structural features. Scanner may be used for capturing optical signals (e.g., barcode images). The electronic components of a scanner may include, for example, a signal processing integrated circuit and an illumination driver. Other structural features may include, for example, raised features on a housing of the lens for screw fastening during assembly.

By way of illustration, the housing for the lens generally aligns the camera module (the image sensor and lens assembly) of the scanner, so that the lens and image sensor can capture images without obstructions. Bosses, i.e. cylindrical protrusions in the housing, are used to align the housing to a bottom surface of a PCB, using screws to hold it in place. Electrical test pads for electrical connections are sometimes placed on the PCB.

It would be beneficial to have improved image sensor module architecture that is capable of being reused in additional or other projects and also cost effective, and that can also be used with plastic lenses. For example, conventional designs generally include electric test pads for focus lens (lens barrel) fixture, such that the focus lens fixture has to be customized for every different barcode scanner PCB, and therefore causing the need for a different design for every different barcode scanner.

As another example, wafer-level camera modules that require minimal assembly and handling have a reflowable part directly soldered to the PCB and managed as a standard Surface-Mount Device (SMD) component within the typical manufacturing process and without a socket or insertion for simplified integration. These modules do not provide or allow for a focusing process to tune the focus of the camera. Furthermore, this design requires the use of glass optical lenses that are resistant to high temperature (during SMT soldering process) and are more expensive compared to optical lenses based on plastic materials. As such, it would be beneficial to have improved image sensor module architecture.

### SUMMARY

This summary provides a high-level overview of various aspects of the technology disclosed herein, and the detailed-description section below provides further description herein. This summary is not intended to identify key features or essential features of the claimed subject matter, nor is it intended to be used as an aid in isolation to determine the scope of the claimed subject matter. The present disclosure is directed, in part, to technology associated with an imaging sensor module, substantially as shown in and/or described in connection with at least one of the figures, and as set forth more completely in the claims.

In an embodiment, a castellated image sensor module comprises an image sensor soldered on a circuit board (e.g., a printed circuit board) having constellated pads along one or more edges of the circuit board, a housing for the lens barrel above the image sensor, and a lens barrel glued to the housing. Stated differently, the housing of the lens barrel may be affixed to the circuit board by an adhesive.

The circuit board may have a castellated pad along an edge of the circuit board, the castellated pad providing an electrical connection from the circuit board to a primary circuit board through the castellated pad (e.g., along an edge of the circuit board). For instance, the castellated pad may have an electrically conductive layer (e.g., copper) that connects the circuit board to the primary circuit board. In some embodiments, the conductive layer may have a nickel and gold based finish.

In some embodiments, the circuit board may have a first plurality of castellated pads along an edge of the circuit board, a second plurality of castellated pads along a second edge of the circuit board, a third plurality of castellated pads along a third edge of the circuit board, and a fourth plurality of castellated pads along a fourth edge of the circuit board. By way of example, each of these pluralities of castellated pads may electrically and mechanically connect the circuit board and the primary circuit board (e.g., based on using a low temperature curing thermally conductive adhesive).

In an embodiment, a method for manufacturing the castellated image sensor module may comprise dispensing a low temperature curing thermally conductive adhesive on a primary circuit board, applying a circuit board, of a castellated camera module, upon the low temperature curing thermally conductive adhesive, the circuit board having castellated pads along one or more edges of the circuit board, and curing the low temperature curing thermally conductive adhesive.

The method may also comprise soldering an image sensor on the circuit board to form an image sensor circuit board module. Additionally, the method may also comprise dispensing an adhesive on the image sensor circuit board module, applying an image sensor module housing upon the adhesive, and curing the adhesive to form the castellated camera module. The method may also comprise installing the primary circuit board, including the castellated camera module electrically and mechanically connected to the primary circuit board, into a scanner.

Another embodiment includes a castellated camera module comprising an image sensor module and a circuit board having castellated pads along one or more edges of the circuit board. In embodiments, the castellated camera module may comprise a primary circuit board that is electrically and mechanically connected with each of the castellated pads. In some embodiments, the image sensor module may comprise an image sensor and a housing for a lens barrel above the image sensor, the lens barrel being affixed to the housing.

This summary is provided to introduce a selection of concepts in a simplified form that are further described below in the detailed description. This summary is not intended to identify key features or essential features of the claimed subject matter, nor is it intended to be used in isolation as an aid in determining the scope of the claimed subject matter.

### BRIEF DESCRIPTION OF THE DRAWINGS

Implementations of the present disclosure are described in detail below with reference to the attached drawing figures, wherein:

FIG. 1 illustrates an example of the architecture of the image sensor module, in accordance with embodiments herein;

FIGS. 2-6 depict different views of the image sensor module, in accordance with embodiments herein; and

FIG. 7 illustrates an example flowchart for manufacturing the image sensor module, in accordance with embodiments herein.

### DETAILED DESCRIPTION

The subject matter of embodiments of the invention is described with specificity herein to meet statutory requirements. However, the description itself is not intended to limit the scope of this patent. Rather, the inventors have contemplated that the claimed subject matter might be embodied in other ways, to include different steps or combinations of steps similar to the ones described in this document, in conjunction with other present or future technologies.

### Definitions

Although the terms “step” and/or “block” may be used herein to connote different elements of methods employed, the terms should not be interpreted as implying any particular order among or between various steps herein disclosed unless and except when the order of individual steps is explicitly described.

In addition, words such as “a” and “an,” unless otherwise indicated to the contrary, may also include the plural as well as the singular. Thus, for example, the constraint of “a feature” is satisfied where one or more features are present.

Furthermore, the term “or” includes the conjunctive, the disjunctive, and both (a or b thus includes either a or b, as well as a and b).

Unless specifically stated otherwise, descriptors such as “first,” “second,” and “third,” for example, are used herein without imputing or otherwise indicating any meaning of priority, physical order, arrangement in a list, or ordering in any way, but are merely used as labels to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

Further, the term “some” may refer to “one or more.” Additionally, an element in the singular may refer to “one or more.” The term “plurality” may refer to “more than one.”

The term “combination” (e.g., one or more combinations thereof) may refer to, for example, “at least one of A, B, or C”; “at least one of A, B, and C”; “at least two of A, B, or C” (e.g., AA, AB, AC, BB, BA, BC, CC, CA, CB); “each of A, B, and C”; and may include multiples of A, multiples of B, or multiples of C (e.g., CCABB, ACBB, ABB, etc.). Other combinations may include more or less than three options associated with the A, B, and C examples.

As used herein, the phrase “based on” shall be construed as a reference to an open set of conditions. For example, an example step that is described as “based on X” may be based on both X and additional conditions, without departing from the scope of the present disclosure. In other words, as used herein, the phrase “based on” shall be construed in the same manner as the phrase “based at least in part on.”

An “image sensor” may be a sensor that converts photons into electrical signals, or a sensor that captures an optical signal (e.g., a barcode image). Examples of an image sensor may be a complementary metal-oxide semiconductor (CMOS) or a charge-coupled device (CCD) sensor that converts light into electrical signals for digital imaging. Other examples of an image sensor may include a time-of-flight sensor (e.g., for three-dimensional imaging and depth sensing), an infrared sensor, a hyperspectral or multispectral sensor, an x-ray sensor, a quantum dot image sensor, another type of image sensor, etc.

A “scanner” is a device that captures data and can convert that data into a digital format for processing. A scanner may use a sensor for detecting an image (e.g., a barcode image) and may decode the image. A scanner may convert physical documents into digital files. A scanner may be a handheld scanner, a barcode scanner, a document scanner, a three-dimensional scanner, a film scanner for scanning photographic films into digital formats, an industrial scanner, a biometric scanner, etc. A scanner may be used during a point-of-sale, for inventory management, logistics, healthcare tracking, treatment planning, paper record digitization, gaming, medical imaging, etc.

### Technological Embodiments

The present technology discussed herein provides for various improvements. For example, the image sensor module technology discussed herein provides for the enhancement of integration into diverse ranges of different electronic boards for a wide range of applications (e.g., from smartphones to industrial equipment, without extensive redesign), enabling scalable and efficient production processes, which previous technologies have not provided.

By way of illustration, the image sensor module technology discussed herein reduces the technical constraints when utilizing a different focus lens fixture for each new scanner (e.g., a barcode scanner). As another example, the image sensor module technology discussed herein allows for the selection of a readily available “on the shelf” image sensor module that reduces the additional strain when manufacturing a barcode scanner, thereby improving the scalability of scanner products. In yet another example, the image sensor module also provides a solution for a focusing process to tune the focus of the image sensor when generating the image sensor module.

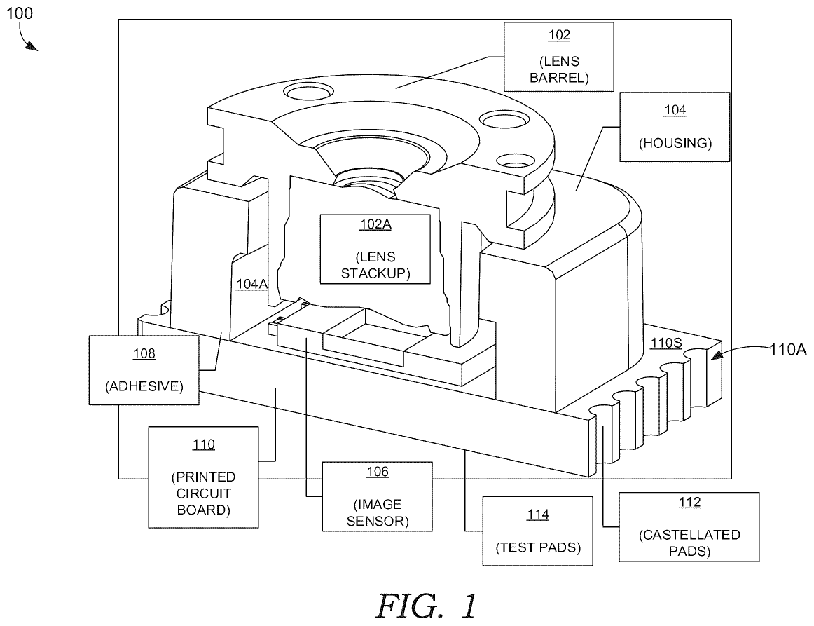

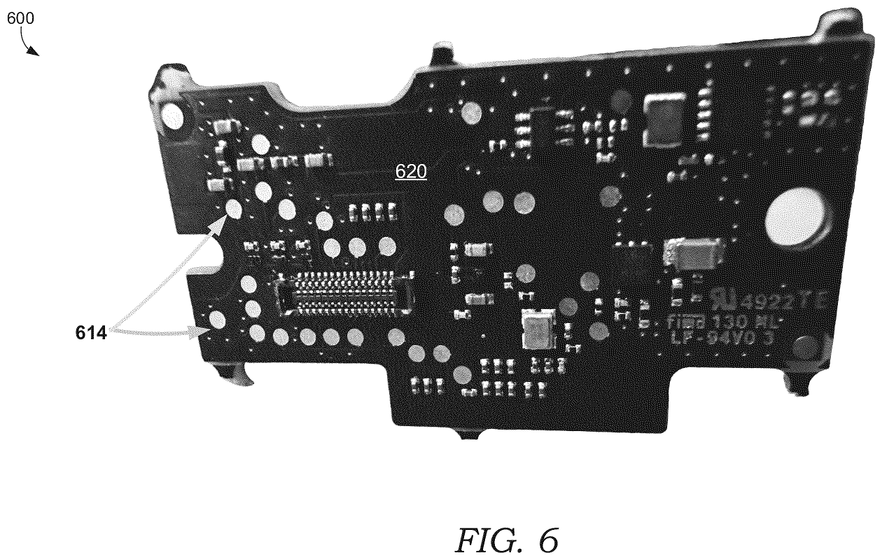

FIG. 1 illustrates example castellated image sensor module 100 including a lens barrel 102, lens stack-up 102A, housing 104, an image sensor 106, an adhesive 108 between the housing 104 and printed circuit board 110, castellated pads 112 along an edge 110A of the printed circuit board 110, and test pads 114 on a bottom surface of a primary circuit board (e.g., test pads 614 on the bottom surface 620 of the primary circuit board of FIG. 6).

Example castellated image sensor module 100 is but one example of a suitable example image sensor module for the technology and techniques disclosed herein, and is not intended to suggest any limitation as to the scope of use or functionality of the invention. Neither should the castellated image sensor module 100 be interpreted as having any dependency or requirement relating to any one or combination of components illustrated.

Example castellated image sensor module 100 includes the image sensor 106. The image sensor 106 can use the photoelectric effect to convert photons into an electric signal. The image sensor 106 may be, for example, a complementary metal-oxide semiconductor (CMOS), a charge-coupled device (CCD) sensor, etc., or one or more combinations thereof. Examples of the CMOS sensor may include a rolling shutter CMOS, a global shutter CMOS, etc. Examples of the CCD sensor may include a full-frame CCD, an interline transfer CCD, etc.

The image sensor 106 may be located on a top surface 110S of the printed circuit board 110 of the image sensor module 100, below the lens barrel 102, and within the housing 104. In embodiments, the inner surface 104A of the housing 104 may not be adjacent to the image sensor 106, such that there is space between the inner surface 104A of the housing 104 and the image sensor 106. The housing 104 aligns and protects the image sensor 106 (and lens barrel 102). The housing 104 may secure the image sensor 106 (e.g., for clear and unobstructed image capturing) without interfering with the optical path or with an electrical component. In embodiments, the image sensor 106 may be arranged in a linear fashion (e.g., linear sensors for 1D scanning) or in a matrix configuration (e.g., image sensors for 2D code scanning).

The lens barrel 102 may comprise a polymer material or another material. The lens barrel 102 may include a mechanism for adjusting the focus (e.g., adjusting the focus to match a distance between a scanner and barcode). The lens barrel 102 may have a functional shape that securely holds and aligns the lens relative to the image sensor 106. The lens barrel 102 may be cylindrical in shape, such that it provides alignment and stability for the lens (e.g., by way of the lens being positioned along an optical axis). The lens barrel 102 may have a stepped design for different lens sizes or for the integration of a filter or spacer. The lens barrel 102 may have a lens holder that secures the lens stack-up 102A and allows for a focal distance between the image sensor 106 and lens.

The housing 104 may comprise a polymer material, a composite material, or another type of material. The housing may have a raised cylindrical feature (e.g. for automated assembly). The housing 104 allows the lens barrel 102 to be positioned relative and aligned to the image sensor 106. The housing 104 may be attached to the top surface 110S of the printed circuit board 110 of the image sensor module 100 by way of adhesive 108. In embodiments, the adhesive 108 is a glue. In other embodiments, the adhesive 108 may be replaced with one or more screws. In embodiments, the adhesive 108 may be an epoxy-based glue, a silicone-based glue, an acrylic-based glue, a polyurethane-based glue, an ultraviolet glue, another type of adhesive, etc., or one or more combinations thereof.

The printed circuit board 110 may be a multilayer interconnection board for use as a surface mount assembly using leadless chip carriers (e.g., a type of integrated circuit board that uses an alternative to pins for electrical connection). By way of example, the pin alternatives may be probed by a dedicated needle fixture and used as electrical connection during a focalization process. The housing 104 may be assembled over the printed circuit board 110 (i.e., on the top surface 110S of the printed circuit board 110) by way of a Surface Mount Technology process (i.e., a process that attaches a component to the surface of a printed circuit board (PCB)). Stated differently, the housing 104 may be affixed to the top surface 110S of the printed circuit board 110 by way of an adhesive curing or epoxy curing process.

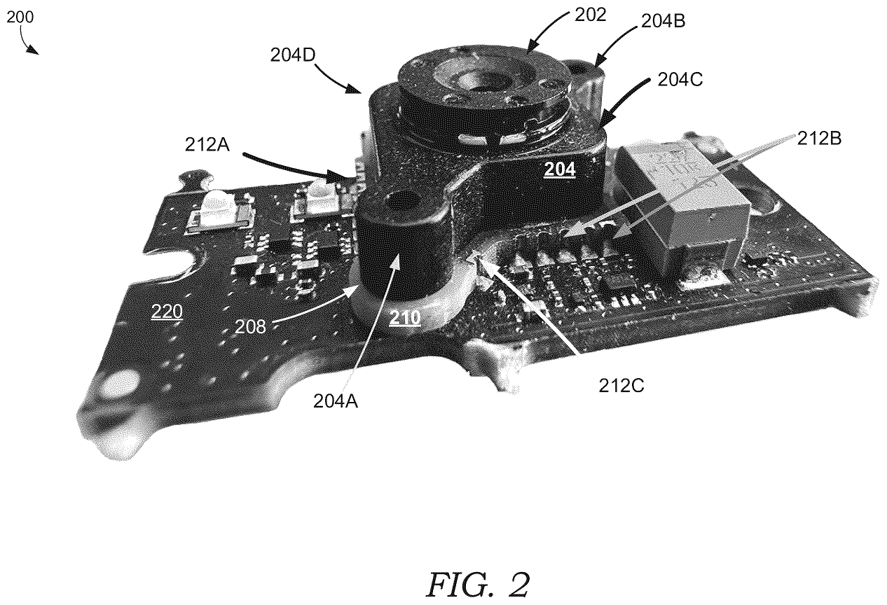

The castellated pads 112 along the edge 110A of the printed circuit board 110 may be plated half-holes dedicated to drive the image sensor 106 to acquire images. Each of the castellated pads 112 may provide an electrical connection between the printed circuit board 110 and a primary circuit board (e.g., primary circuit board 220 of FIG. 2). For example, the electrical connection may be provided through the edge 110A of the printed circuit board 110 to the primary circuit board. In embodiments, the printed circuit board 110 may have a plurality of castellated pads 112 along one or more edges, each of which connected to the primary circuit board.

The castellated pads 112 may be electrical contact points that provide an interface from the printed circuit board 110 (e.g., between the printed circuit board 110 and the primary circuit board 220 of FIG. 2). In embodiments, the castellated pads 112 may establish both an electrical and mechanical connection (e.g., during a surface-mount assembly process). In embodiments, the castellated pads each have a conductive layer (e.g., copper) that causes the printed circuit board 110 to be the electrical interface (i.e., the conductive layer connecting the printed circuit board 110 to the primary circuit board). In some embodiments, the conductive layer has a nickel and gold based finish (e.g., for corrosion resistance, an electro-less nickel immersion gold for enhancing solderability).

FIG. 2 illustrates an example of an assembled castellated image sensor module 200 that has a lens barrel 202, a housing 204 for the lens barrel 202 and the image sensor (e.g., image sensor 106 of FIG. 1) located above a printed circuit board 210, an adhesive 208 between the housing 204 and printed circuit board 210, a first plurality of castellated pads 212A along an edge of the printed circuit board 210, a second plurality of castellated pads 212B along a second edge of the printed circuit board 210, a castellated pad 212C along a curved edge (e.g., concave) of the printed circuit board 210, and a primary circuit board 220. The primary circuit board 220 may be electrically and mechanically connected to the printed circuit board 210 through each of the castellated pads 212A, 212B, 212C (e.g., by way of a low temperature curing thermally conductive adhesive).

Example castellated image sensor module 200 is but one example of a suitable example castellated image sensor module for the technology and techniques disclosed herein, and is not intended to suggest any limitation as to the scope of use or functionality of the invention. Neither should the castellated image sensor module 200 be interpreted as having any dependency or requirement relating to any one or combination of components illustrated. By way of illustration, in other embodiments, the castellated image sensor module 200 may take the form of other shapes (e.g., a square having four edges populated with castellated pads).

In embodiments, the housing 204 has a first lobe 204A, a second lobe 204B, a third lobe 204C, and a fourth lobe 204D. In embodiments, the first lobe 204A and the second lobe 204B may each have a cylindrical shape that has an open space running through its length. In embodiments, the first lobe 204A and the second lobe 204B have similar shapes, and the third lobe 204C and fourth lobe 204D have a different size and shape. Other embodiments of the housing 204 may have different lobe sizes and shapes (e.g., more square than lobe shaped sides). Other embodiments of the housing 204 may have different configurations.

The first plurality of castellated pads 212A may be located on the printed circuit board 210 below and between the first lobe 204A and the fourth lobe 204D. The second plurality of castellated pads 212B (e.g., five castellated pads) and the castellated pad 212C may be located on the printed circuit board 210 below and between the first lobe 204A and the third lobe 204C, and the castellated pad 212C may be located closer to the first lobe 204A than the second plurality of castellated pads 212B. In other embodiments, the castellated pads 212A, 212B, 212C may be located on the printed circuit board 210 below and between parts of the housing 204 that are a different shape or form than a lobe.

As such, the castellated image sensor module 200 has a castellated pad (e.g., one of the first plurality of castellated pads 212A) along an edge of the printed circuit board 210. The castellated pads 212A, 212B may provide an electrical connection between the printed circuit board 210 and the primary circuit board 220 based on conductive glue between the printed circuit board 210 and the primary circuit board 220. For example, on the top surface of the primary circuit board 220, there are pads that match the positioning of the castellated pads 212A, 212B, 212C and an electrical connection between the castellated pads 212A, 212B, 212C and the pads on the top surface of the primary circuit board 220 is provided by the conductive glue.

Each of the castellated pads 212A, 212B, and 212C may be electrical contact points that provide an electrical interface between the printed circuit board 210 and the primary circuit board 220. In embodiments, each of the castellated pads 212A, 212B, and 212C may establish an electrical and mechanical connection between the printed circuit board 210 and the primary circuit board 220. In embodiments, the castellated pads each have a conductive layer (e.g., copper) that causes the printed circuit board 210 to interface with the primary circuit board 220 (e.g., based on a low temperature curing thermally conductive adhesive and the pads on the surface of the primary circuit board 220). In some embodiments, one or more of the copper layers have a corrosion resistant finish, a finish for enhancing solderability, etc., or one or more combinations thereof. In some embodiments, one or more of the copper layers have a different finish that the other copper layers. In some embodiments, one or more of the castellated pads have different conductive material than another castellated pad.

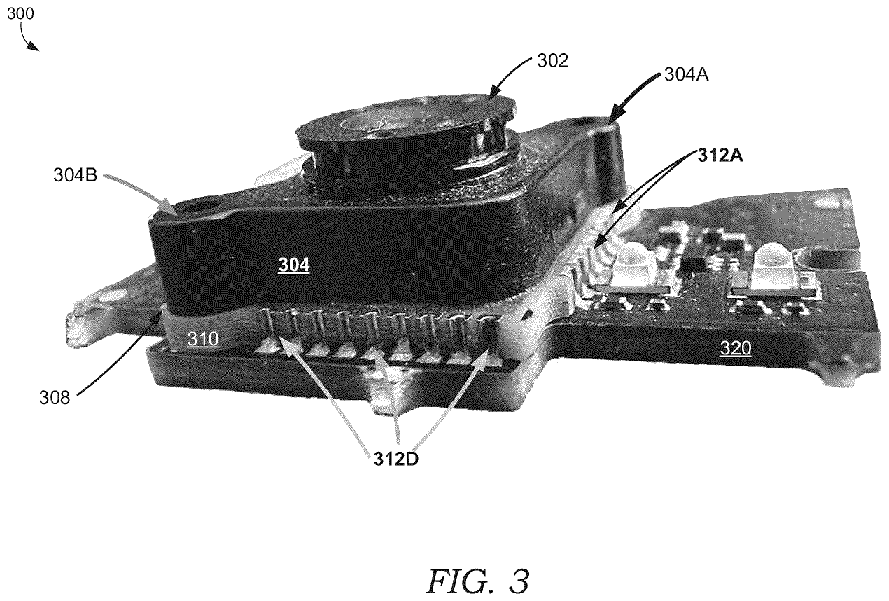

FIG. 3 illustrates an example of an image sensor module 300 that has a lens barrel 302, a housing 304 (e.g., having a first lobe 304A and a second lobe 304B) for the lens barrel 302 and the image sensor (e.g., image sensor 106 of FIG. 1) located above a printed circuit board 310, an adhesive 308 between the housing 304 and printed circuit board 310, a first plurality of castellated pads 312A (e.g., seven castellated pads) along an edge of the printed circuit board 310, a third plurality of castellated pads 312D (e.g., nine castellated pads) along a third edge of the printed circuit board 310, and a primary circuit board 320.

Example castellated image sensor module 300 is but one example of a suitable example image sensor module for the technology and techniques disclosed herein, and is not intended to suggest any limitation as to the scope of use or functionality of the invention. Neither should the castellated image sensor module 300 be interpreted as having any dependency or requirement relating to any one or combination of components illustrated. By way of illustration, in other embodiments, the housing 304 may be shaped differently.

The first plurality of castellated pads 312A may be cylindrical halves with a conductive layer from a top surface of the printed circuit board 310 to the bottom surface of the printed circuit board 310. The first plurality of castellated pads 312A may be located on the edge of the printed circuit board 310 below the first lobe 304A and the second lobe 304B of the housing 304. The first plurality of castellated pads 312A may be located on the edge of the printed circuit board 310 below and between the first lobe 304A and the second lobe 304B of the housing 304.

The third plurality of castellated pads 312D may be cylindrical halves with a conductive layer across the edge of the printed circuit board 310. The third plurality of castellated pads 312D may be located on the edge of the printed circuit board 310 below and between the first lobe 304A and the second lobe 304B. The first plurality of castellated pads 312A may be located closer to the first lobe 304A than the third plurality of castellated pads 312D. The third plurality of castellated pads 312D may be located closer to the second lobe 304B than the first plurality of castellated pads 312A.

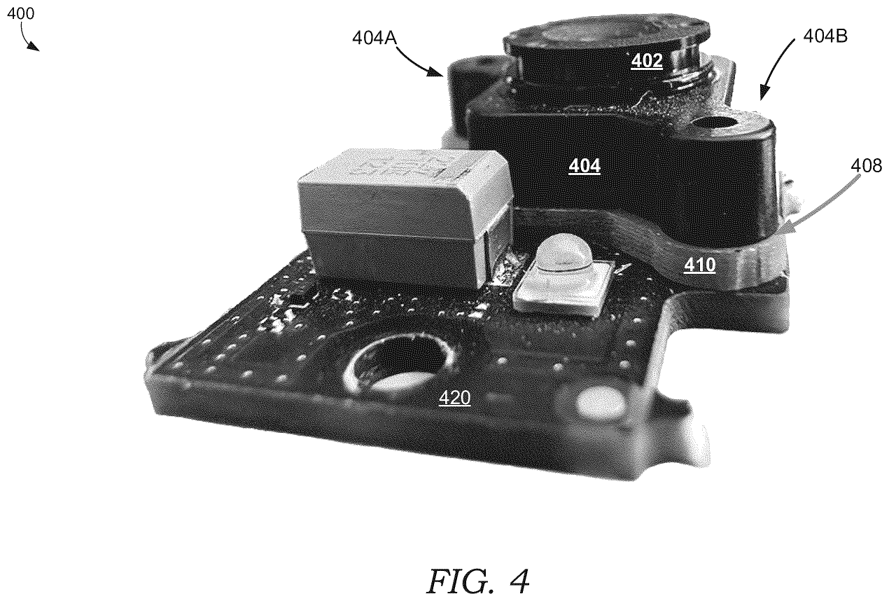

FIG. 4 illustrates example image sensor module 400 that has a lens barrel 402, a housing 404 (having a first lobe 404A and a second lobe 404B) for the lens barrel 402 and the image sensor (e.g., image sensor 106 of FIG. 1) located above a printed circuit board 410, an adhesive 408 between the housing 404 and printed circuit board 410, and a primary circuit board 420.

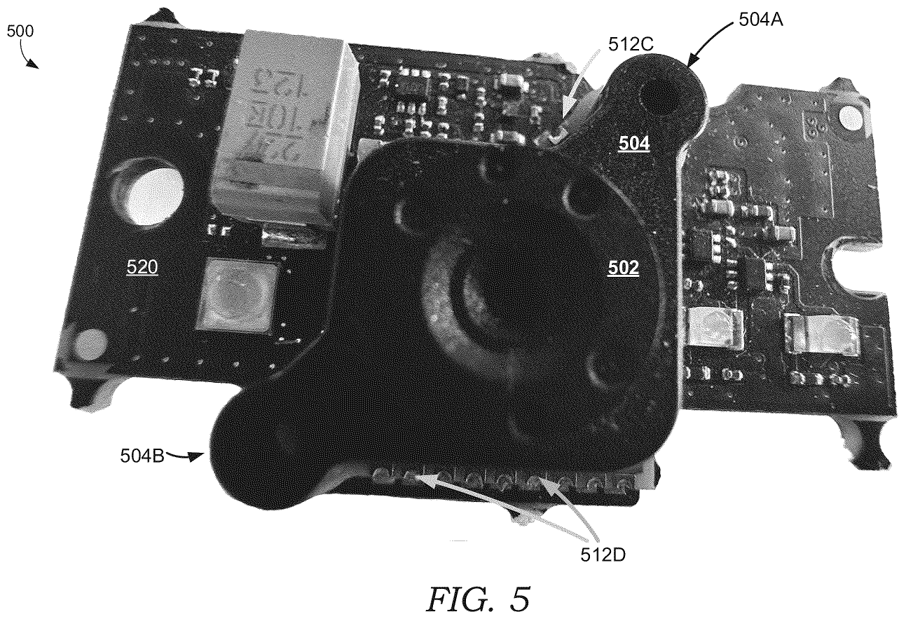

FIG. 5 illustrates an aerial perspective of example image sensor module 500 that has a lens barrel 502, a housing 504 (having a first lobe 504A and a second lobe 504B) for the lens barrel 502 and the image sensor (e.g., image sensor 106, of FIG. 1, above a printed circuit board), castellated pad 512C (e.g., along a curved edge of the printed circuit board), a third plurality of castellated pads 512D (e.g., nine castellated pads along a third edge of the printed circuit board), and a primary circuit board 520. The third plurality of castellated pads 512D are electrically connected to the primary circuit board 520 (e.g., by way of a copper layer that connects the printed circuit board to the primary circuit board 520).

FIG. 6 illustrates a bottom surface 620 of a primary circuit board of the example image sensor module 600 (e.g., including the lens barrel 202, housing 204, printed circuit board 210, and castellated pads 212A, 212B, and 212C of FIG. 2 located on the front surface of the primary circuit board). The bottom surface 620 of the primary circuit board has a plurality of test pads 614 (e.g., test pads 114 of FIG. 1). The plurality of test pads 614 may provide electrical connections (e.g., for alignment and functionality of the lens barrel and image sensor, and allowing images to be captured based on utilizing the image sensor). The plurality of test pads 614 may comprise a conductive material (e.g., copper). The plurality of test pads 614 may also provide contact points for testing equipment (e.g., without having to solder permanent wires or connectors). The plurality of test pads 614 may have one or more different finishes, such as electroless nickel immersion gold, organic solderability preservative, hard gold, another type of conductive and corrosive resistant finish, etc., or one or more combinations thereof.

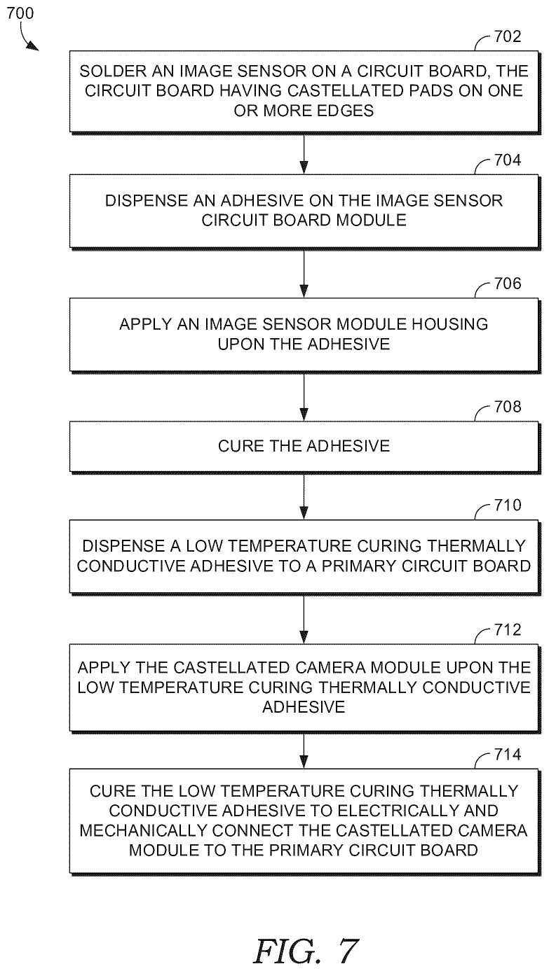

FIG. 7 includes example flowchart 700 (e.g., for manufacturing the castellated image sensor module of FIGS. 1-6).

Example flowchart 700 begins at step 702 with soldering an image sensor (e.g., image sensor 106) on the circuit board (e.g., circuit board 110, 210, 310, 410), having castellated pads along one or more edges, to form an image sensor circuit board module. Step 704 involves dispensing an adhesive (e.g., glue) on the image sensor circuit board module. For example, the adhesive may be added to the image sensor circuit board module in the pattern of the perimeter of the bottom of the housing 104 of FIG. 1. As another example, the adhesive may be added to the image sensor circuit board module in dots that mimic the perimeter of the bottom of the housing 104 of FIG. 1. In other embodiments, the adhesive may instead be added along bottom of the housing 104 of FIG. 1 prior to placing the housing onto the image sensor circuit board module.

Step 706 involves applying the image sensor module housing (e.g., housing 104 of FIG. 1, housing 404 of FIG. 4) upon the adhesive, and step 708 involves curing the adhesive to form the castellated camera module. The curing may include hardening the adhesive by applying heat, an ultraviolet light, etc., or one or more combinations thereof, such that the adhesive bonds (mechanical bond) the image sensor module housing and the image sensor circuit board module.

In some embodiments, after curing the adhesive, the lens barrel (e.g., lens barrel 102 of FIG. 1), being housed by the image sensor module housing, may be focused. In some embodiments, the lens barrel may be focused by a semi-automated focusing machine (e.g., with multiple test pads connecting the image sensor module from the bottom side of the primary circuit board).

Step 710 includes dispensing an electrically conductive thermal glue (e.g., heat conductive glue, a heat curable epoxy, an adhesive that provides both electrical conductivity and thermal conductivity, a silver-filled epoxy, a graphite-based adhesive, a copper-filled adhesive, etc., or one or more combinations thereof) to a primary circuit board (e.g., primary circuit board 220 of FIG. 2), and step 712 includes applying the circuit board (e.g., the printed circuit board 310 of FIG. 3 having castellated pads along one or more edges of the circuit board), of the castellated camera module, upon the low temperature curing thermally conductive adhesive. (Alternatively, in other embodiments, the electrically conductive thermal glue may be applied to the bottom of the circuit board, and then the castellated camera module may be placed on the primary circuit board.)

At step 714, after dispensing the electrically conductive thermal glue, the electrically conductive thermal glue is cured (e.g., heat-cured, UV-cured, room-temperature cured, etc., or one or more combinations thereof), such that the electrically conductive thermal glue connects (mechanically and electrically) the circuit board of the castellated camera module to the primary circuit board. The castellated pads may be electrical contact points that provide an electrical interface between the castellated camera module and the primary circuit board.

In embodiments, based on the connection between the image sensor module circuit board and the primary circuit board, the primary circuit board (e.g., including the castellated camera module) may be installed into a scanner. Additionally or alternatively, before or after connecting the circuit board and the primary circuit board, test pads (e.g., test pads 614 of FIG. 6) may be affixed on a bottom surface of the primary circuit board, and a focalization process (e.g., measuring focus performance, fine-tuning the focus via calibration) may be implemented using the test pads.

Having identified various components utilized herein, it should be understood that any number of components and arrangements may be employed to achieve the desired functionality within the scope of the present disclosure. For example, the components in the embodiments depicted in the figures are shown with lines for the sake of conceptual clarity. Other arrangements of these and other components may also be implemented. For example, although some components are depicted as single components, many of the elements described herein may be implemented as discrete or distributed components or in conjunction with other components, and in any suitable combination and location. Some elements may be omitted altogether. Moreover, various functions described herein as being performed by one or more entities may be carried out by hardware, firmware, and/or software. For instance, various functions may be carried out by a processor executing instructions stored in memory. As such, other arrangements and elements (for example, machines, interfaces, functions, orders, and groupings of functions, and the like) can be used in addition to, or instead of, those shown.

Embodiments of the present disclosure have been described with the intent to be illustrative rather than restrictive. Embodiments described in the paragraphs above may be combined with one or more of the specifically described alternatives. In particular, an embodiment that is claimed may contain a reference, in the alternative, to more than one other embodiment. The embodiment that is claimed may specify a further limitation of the subject matter claimed. Alternative embodiments will become apparent to readers of this disclosure after and because of reading it. Alternative means of implementing the aforementioned can be completed without departing from the scope of the claims below. Certain features and sub-combinations are of utility and may be employed without reference to other features and sub-combinations and are contemplated within the scope of the claims.

Many different arrangements of the various components depicted, as well as components not shown, are possible without departing from the scope of the claims below. Embodiments in this disclosure are described with the intent to be illustrative rather than restrictive. Alternative embodiments will become apparent to readers of this disclosure after and because of reading it. Alternative means of implementing the aforementioned can be completed without departing from the scope of the claims below. Certain features and subcombinations are of utility and may be employed without reference to other features and subcombinations and are contemplated within the scope of the claims.

In the preceding detailed description, reference is made to the accompanying drawings which form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the preceding detailed description is not to be taken in the limiting sense, and the scope of embodiments is defined by the appended claims and their equivalents.

The invention claimed is:

1. A castellated image sensor module comprising:
an image sensor;
a lens barrel above the image sensor;
a housing of the lens barrel; and
a circuit board having castellated pads along one or more edges of the circuit board.

2. The castellated image sensor module of claim 1, further comprising a primary circuit board electrically and mechanically connected with the castellated pads.

3. The castellated image sensor module of claim 2, the primary circuit board having a plurality of test pads on a bottom surface of the primary circuit board.

4. The castellated image sensor module of claim 2, the circuit board having the castellated pads along at least two edges of the circuit board.

5. The castellated image sensor module of claim 2, the circuit board having the castellated pads along at least three edges of the circuit board.

6. The castellated image sensor module of claim 2, each of the castellated pads having a copper layer that connects the circuit board to the primary circuit board.

7. The castellated image sensor module of claim 6, the copper layer having a nickel and gold based finish.

8. The castellated image sensor module of claim 5, further comprising a plurality of castellated pads along a fourth edge of the circuit board, the plurality of castellated pads also electrically and mechanically connected to the primary circuit board.

9. The castellated image sensor module of claim 5, each of the castellated pads, along the at least three edges, having a copper layer that connects the circuit board to the primary circuit board.

10. The castellated image sensor module of claim 2, the circuit board being connected to the primary circuit board by a low temperature curing thermally conductive adhesive.

11. A method comprising:
dispensing a low temperature curing thermally conductive adhesive on a primary circuit board;
applying a circuit board, of a castellated camera module, upon the low temperature curing thermally conductive adhesive, the circuit board having castellated pads along one or more edges of the circuit board; and
curing the low temperature curing thermally conductive adhesive.

12. The method according to claim 11, further comprising focusing a lens barrel being housed by an image sensor module housing of the castellated camera module.

13. The method according to claim 11, further comprising:
soldering an image sensor on the circuit board to form an image sensor circuit board module;
dispensing an adhesive on the image sensor circuit board module;
applying an image sensor module housing upon the adhesive; and
curing the adhesive to form the castellated camera module.

14. The method according to claim 13, further comprising installing the primary circuit board, including the castellated camera module electrically and mechanically connected to the primary circuit board, into a scanner.

15. The method according to claim 13, further comprising affixing test pads on a bottom surface of the primary circuit board.

16. The method according to claim 11, further comprising installing the primary circuit board, including the castellated camera module electrically and mechanically connected to the primary circuit board, into a scanner.

17. The method according to claim 16, further comprising affixing test pads on a bottom surface of the primary circuit board.

18. A castellated camera module including an image sensor module and a circuit board having castellated pads along one or more edges of the circuit board.

19. The castellated camera module of claim 18, further comprising a primary circuit board that is electrically and mechanically connected with each of the castellated pads.

20. The castellated camera module of claim 18, the image sensor module comprising an image sensor and a housing for a lens barrel above the image sensor, the lens barrel being affixed to the housing.
